(19) United States
(12) Patent Application Publication
(10) Pub. No.: US 2025/0383241 A1
(43) Pub. Date: Dec. 18, 2025

(54) Apparatus for Diagnosing State of Battery Cell and Method Thereof

(71) Applicants: HYUNDAI MOTOR COMPANY, Seoul (KR); KIA CORPORATION, Seoul (KR); Hongik University Industry-Academia Cooperation Foundation, Seoul (KR)

(72) Inventors: Jin Woo Park, Hwaseong-si (KR); Yoo Hong Jang, Hwaseong-si (KR); Hyo Kyung Lee, Hwaseong-si (KR); Min Hyeok Hwang, Incheon (KR); Hwa Joo Jung, Seoul (KR); Sung Jin Park, Seoul (KR)

(73) Assignees: HYUNDAI MOTOR COMPANY, Seoul (KR); KIA CORPORATION, Seoul (KR); Hongik University Industry-Academia Cooperation Foundation, Seoul (KR)

(21) Appl. No.: 18/917,330

(22) Filed: Oct. 16, 2024

(30) Foreign Application Priority Data
Jun. 18, 2024 (KR) 10-2024-0079141

(51) Int. Cl. G01K 3/00; H01M 10/48

(52) U.S. Cl. CPC G01K 3/005; H01M 10/486; H01M 2220/20

(57) ABSTRACT

Disclosed are an apparatus and method for a state of a battery cell. The apparatus diagnoses the state of the battery cell with high accuracy by dividing the battery cell into a plurality of regions, constructing a Randle circuit for each region, determining a current value and a resistance value of each region based on the Randle circuit, determining the amount of internal heat generation of each region by using the current value and the resistance value, determining an amount of heat transfer and an amount of heat convection of each region based on an outside temperature value and a previous temperature value of each region, estimating a temperature of each region based on the amount of internal heat generation, the amount of heat transfer, and the amount of heat convection of each region, and diagnosing the state of the battery cell by using the temperature of each region.

### CROSS-REFERENCE TO RELATED APPLICATION

This application claims the benefit of priority to Korean Patent Application No. 10-2024-0079141, filed in the Korean Intellectual Property Office on Jun. 18, 2024, the entire contents of which are incorporated herein by reference.

### TECHNICAL FIELD

The present disclosure relates to a technology for diagnosing the state of a battery cell based on the temperature of each part of the battery cell.

### BACKGROUND

In general, an electric vehicle, which is a vehicle driven by electric energy, is equipped with a battery including a plurality of battery cells that store electric energy. Such battery cells convert chemical energy into electrical energy to supply electrical energy (discharge), or convert electrical energy supplied from an outside into chemical energy to store it (charge).

Because an electric vehicle is driven using electrical energy stored in a battery as a power source, the performance of the vehicle is determined by the performance of the battery. Therefore, in order to improve the performance of an electric vehicle, it is required to manage the battery to maximize the performance.

In recent years, because battery cells with excellent performance are used to improve the power source of a vehicle, and the number of battery cells increases gradually, it is more required to manage a battery. Such battery management is generally performed by a battery management system (BMS).

The battery management system measures cell state information including a voltage, a current, a temperature, and the like of a battery cell from a battery module provided in an electric vehicle, uses the cell state information and option values for controlling battery cells to manage the battery cells, and performs cell balancing to maintain balance between the battery cells.

The cell balancing is one of the control operations of a battery management system that equalizes the voltages or charge amounts of battery cells. Each battery cell of a battery module may have differences in electrical characteristics even when the battery cells are manufactured under the same manufacturing conditions and environment, and may also have differences in electrical characteristics even when the battery cells are mounted and operated in an electric vehicle.

Due to such differences in electrical characteristics, even when battery cells are charged and discharged with the same current, voltage imbalance or residual charge imbalance may occur between interconnected battery cells, and the voltage imbalance or residual charge imbalance between battery cells may cause the available voltage range of battery cells to decrease or the charging and discharging cycle to be shorter.

Meanwhile, a conventional technology for diagnosing the state of a battery cell includes a temperature sensor on one side of the battery cell, and diagnosing the state of the battery cell based on the temperature measured by the temperature sensor.

According to the conventional technology, because the state of the battery cell is simply diagnosed based on the temperature of one side of the battery cell without considering the temperature difference between parts of the battery cell, when the temperature of one side is normal even though the temperature of an opposite side of the battery cell is abnormal, it may be determined that the state of the battery cell is normal.

The matters described in this background section are intended to promote an understanding of the background of the disclosure and may include matters that are not already known to those of ordinary skill in the art.

### SUMMARY

The present disclosure has been made to solve the above-mentioned problems occurring in the prior art while advantages achieved by the prior art are maintained intact.

One aspect of the present disclosure provides an apparatus and a method capable of diagnosing the state of the battery cell with high accuracy by dividing the battery cell into a plurality of regions, constructing a Randle circuit for each region, determining a current value and a resistance value of each region based on the Randle circuit, determining the amount of internal heat generation of each region by using the current value and the resistance value, determining an amount of heat transfer and an amount of heat convection of each region based on an outside temperature value and a previous temperature value of each region, estimating a temperature of each region based on the amount of internal heat generation, the amount of heat transfer, and the amount of heat convection of each region, and diagnosing the state of the battery cell by using the temperature of each region.

Another aspect of the present disclosure provides an apparatus and a method capable of diagnosing the state of the battery cell with high accuracy by dividing the battery cell into a plurality of regions, constructing a Randle circuit for each region, determining a current value and a resistance value of each region based on the Randle circuit, determining the amount of internal heat generation of each region by using the current value and the resistance value, determining an amount of heat transfer and an amount of heat convection of each region based on an outside temperature value and a previous temperature value of each region, estimating a temperature of each region based on the amount of internal heat generation, the amount of heat transfer, and the amount of heat convection of each region, and diagnosing the state of the battery cell by using a temperature outside a normal range among temperatures of the plurality of regions.

Still another aspect of the present disclosure provides an apparatus and a method capable of diagnosing the state of the battery cell with high accuracy by dividing the battery cell into a plurality of regions, constructing a Randle circuit for each region, determining a current value and a resistance value of each region based on the Randle circuit, determining the amount of internal heat generation of each region based on the current value and the resistance value, determining an amount of heat transfer and an amount of heat convection of each region based on an outside temperature value and a previous temperature value of each region, estimating a temperature of each region based on the amount of internal heat generation, the amount of heat transfer, and the amount of heat convection of each region, classifying the temperature of each region into a plurality of temperature sections, and diagnosing the state of the battery cell based on the temperature section with a highest risk among the plurality of temperature sections.

The technical problems to be solved by the present disclosure are not limited to the aforementioned problems, and any other technical problems not mentioned herein will be clearly understood from the following description by those skilled in the art to which the present disclosure pertains. Also, it may be easily understood that the objects and advantages of the present disclosure may be realized by the units and combinations thereof recited in the claims.

According to an aspect of the present disclosure, an apparatus for diagnosing a state of a battery cell includes the battery cell provided in a vehicle, and a controller that divides the battery cell into a plurality of regions, determines an amount of heat transfer, an amount of internal heat generation, and an amount of heat convection in each region, estimates a temperature of each region based on the amount of internal heat generation, the amount of heat transfer, and the amount of heat convection of each region, and diagnoses the state of the battery cell by using the temperature of each region.

According to an embodiment, the controller may diagnose the state of the battery cell by using a temperature outside a normal range among temperatures of the plurality of regions.

According to an embodiment, the controller may classify the temperature of each region into a plurality of temperature sections and diagnose the state of the battery cell based on the temperature section with a highest risk among the plurality of temperature sections.

According to an embodiment, the controller may construct a Randle circuit for each region, determine a current value and a resistance value of the Randle circuit, and determine the amount of internal heat generation of each region based on the current value and resistance value.

According to an embodiment, the controller may determine an amount of heat transfer in an x-axis direction and an amount of heat transfer in a y-axis direction for each region.

According to an embodiment, the controller may determine the amount of heat transfer in the x-axis direction for each region by using a previous temperature value of each region and a heat conduction coefficient in the x-axis direction.

According to an embodiment, the controller may determine the amount of heat transfer in the y-axis direction for each region by using a previous temperature value of each region and a heat conduction coefficient in the y-axis direction.

According to an embodiment, the apparatus may further include a temperature sensor that measures an outside temperature value.

According to an embodiment, the controller may determine the amount of heat convection in each region by using a convective heat transfer coefficient, a convective heat transfer surface area, a previous temperature value of each region, the outside temperature value, and a volume of the battery cell.

According to an embodiment, the controller may divide the battery cell into 3×5 regions or 4×4 regions.

According to an aspect of the present disclosure, a method of diagnosing a state of a battery cell includes dividing, by a controller, the battery cell provided in a vehicle into a plurality of regions, determining, by the controller, an amount of heat transfer, an amount of internal heat generation, and an amount of heat convection in each region, estimating, by the controller, a temperature of each region based on the amount of internal heat generation, the amount of heat transfer, and the amount of heat convection of each region, and diagnosing, by the controller, the state of the battery cell by using the temperature of each region.

According to an embodiment, the diagnosing of the state of the battery cell may include diagnosing the state of the battery cell by using a temperature outside a normal range among temperatures of the plurality of regions.

According to an embodiment, the diagnosing of the state of the battery cell may include classifying the temperature of each region into a plurality of temperature sections, and diagnosing the state of the battery cell based on the temperature section with a highest risk among the plurality of temperature sections.

According to an embodiment, the determining of the amount of heat transfer, the amount of internal heat generation, and the amount of heat convection in each region includes constructing a Randle circuit for each region, determining a current value and a resistance value of the Randle circuit, and determining the amount of internal heat generation of each region based on the current value and resistance value.

According to an embodiment, the determining of the amount of heat transfer, the amount of internal heat generation, and the amount of heat convection in each region may include determining an amount of heat transfer in an x-axis direction for each region, and determining an amount of heat transfer in a y-axis direction for each region.

According to an embodiment, the determining of the amount of heat transfer in the x-axis direction for each region may include determining the amount of heat transfer in the x-axis direction for each region by using a previous temperature value of each region and a heat conduction coefficient in the x-axis direction.

According to an embodiment, the determining of the amount of heat transfer in the y-axis direction for each region may include determining the amount of heat transfer in the y-axis direction for each region by using a previous temperature value of each region and a heat conduction coefficient in the y-axis direction.

According to an embodiment, the method may further include measuring, by a temperature sensor, an outside temperature value.

According to an embodiment, the determining of the amount of heat transfer, the amount of internal heat generation, and the amount of heat convection in each region may include determining the amount of heat convection in each region by using a convective heat transfer coefficient, a convective heat transfer surface area, a previous temperature value of each region, the outside temperature value, and a volume of the battery cell.

According to an embodiment, the dividing of the battery cell into the plurality of regions may include dividing the battery cell into 3×5 regions or 4×4 regions.

### BRIEF DESCRIPTION OF THE DRAWINGS

The above and other objects, features and advantages of the present disclosure will be more apparent from the following detailed description taken in conjunction with the accompanying drawings:

FIG. 1 is a block diagram illustrating an apparatus for diagnosing the state of a battery cell according to an embodiment of the present disclosure;

FIG. 2 is a diagram illustrating an example of a dOCV/dT map stored in storage in an apparatus for diagnosing a state of a battery cell according to an embodiment of the present disclosure;

FIG. 3 is a diagram illustrating an example of a result of dividing a battery cell into a plurality of regions by the controller provided in an apparatus for diagnosing the state of a battery cell according to an embodiment of the present disclosure;

FIG. 4 is a diagram illustrating another example of a result of dividing a battery cell into a plurality of regions by the controller provided in an apparatus for diagnosing the state of a battery cell according to an embodiment of the present disclosure;

FIG. 5 is a diagram illustrating an example of a Randle circuit for each region of a battery cell generated by a controller provided in an apparatus for diagnosing the state of a battery cell according to an embodiment of the present disclosure;

FIG. 6 is a diagram illustrating examples of heat conduction and heat convection in a target region of a battery cell generated by a controller provided in an apparatus for diagnosing a state of a battery cell according to an embodiment of the present disclosure;

FIG. 7 is a diagram illustrating a first example of the temperature estimation performance of an apparatus for diagnosing a state of a battery cell according to an embodiment of the present disclosure.

FIG. 8 is a diagram illustrating a second example of the temperature estimation performance of an apparatus for diagnosing a state of a battery cell according to an embodiment of the present disclosure;

FIG. 9 is a diagram illustrating a third example of the temperature estimation performance of an apparatus for diagnosing a state of a battery cell according to an embodiment of the present disclosure;

FIG. 10 is a diagram illustrating an example of a result of comparing the performances of an apparatus for diagnosing a state of a battery cell according to an embodiment of the present disclosure;

FIG. 11 is a flowchart illustrating a method of diagnosing a state of a battery cell according to an embodiment of the present disclosure; and

FIG. 12 is a block diagram illustrating a computing system for executing a method of diagnosing a state of a battery cell according to each embodiment of the present disclosure.

### DETAILED DESCRIPTION

Hereinafter, some embodiments of the present disclosure will be described in detail with reference to the exemplary drawings. In adding the reference numerals to the components of each drawing, it should be noted that the identical or equivalent component is specified by the identical numeral even when they are displayed on other drawings. Further, in describing the embodiment of the present disclosure, a detailed description of the related known configuration or function will be omitted when it is determined that it interferes with the understanding of the embodiment of the present disclosure.

In addition, terms, such as first, second, A, B, (a), (b) or the like may be used herein when describing components of the present disclosure. The terms are provided only to distinguish the elements from other elements, and the essences, sequences, orders, and numbers of the elements are not limited by the terms. In addition, unless defined otherwise, all terms used herein, including technical or scientific terms, have the same meanings as those generally understood by those skilled in the art to which the present disclosure pertains. The terms defined in the generally used dictionaries should be construed as having the meanings that coincide with the meanings of the contexts of the related technologies, and should not be construed as ideal or excessively formal meanings unless clearly defined in the specification of the present disclosure.

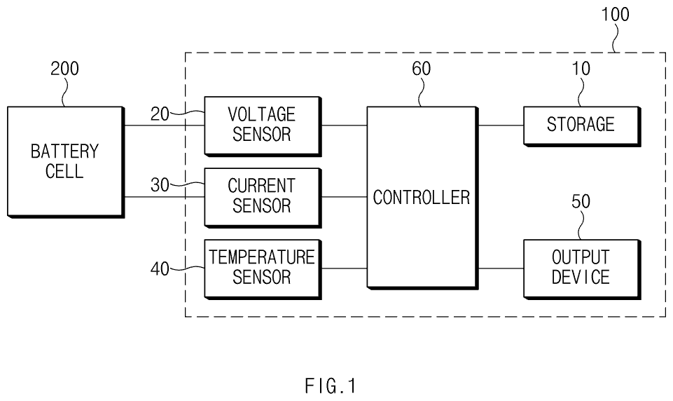

FIG. 1 is a block diagram illustrating an apparatus for diagnosing the state of a battery cell according to an embodiment of the present disclosure.

As shown in FIG. 1, an apparatus for diagnosing the state of a battery cell according to an embodiment of the present disclosure may include storage 10, a voltage sensor 20, a current sensor 30, a temperature sensor 40, an output device 50, and a controller 60. In this case, depending on a scheme of implementing the apparatus for diagnosing the state of a battery cell according to an embodiment of the present disclosure, components may be combined with each other to be implemented as one, or some components may be omitted.

Regarding each component, first, the storage 10 may store various logic, algorithms, and programs required in the process of dividing a battery cell 200 provided in a vehicle into a plurality of regions, constructing a Randle circuit for each region, determining a current value and a resistance value of each region based on the Randle circuit, determining the amount of internal heat generation of each region by using the current value and the resistance value, determining an amount of heat transfer and an amount of heat convection of each region based on an outside temperature value and a previous temperature value of each region, estimating a temperature of each region based on the amount of internal heat generation, the amount of heat transfer, and the amount of heat convection of each region, and diagnosing the state of the battery cell 200 by using the temperature of each region.

The storage 10 may store a first lookup table in which a voltage value OCVₙ corresponding to the state of charge (SOC) value and temperature value for each region of the battery cell 200 is recorded. Therefore, the controller 60 may determine the voltage value of a target region by using the SOC and temperature value of the target region based on the first lookup table. In this case, the SOC value is a SOC value SOCₙ₋₁ determined at a previous time point, and the temperature value is also a temperature value Tₙ₋₁ determined at the previous time point. In addition, the initial value of the SOC value for each region of the battery cell 200 may be set as the result of dividing the OSC value of the battery cell 200 by the number of regions, and then the initial value may be updated based on the current value for each region of the battery cell 200. In addition, the temperature value may also be set to an initial value.

The storage 10 may store a second lookup table in which a first resistance value R₀ corresponding to the current value, SOC value, and temperature value for each region of the battery cell 200 is recorded. Accordingly, the controller 60 may determine the first resistance value of the target region by using the current value, SOC value, and temperature value of the target region, based on the second lookup table. In this case, the current value is a current value Iₙ at the current time point, the SOC value is a SOC value SOCₙ₋₁ determined at the previous time point, and the temperature value is also a temperature value Tₙ₋₁ determined at the previous time point.

The storage 10 may store a third lookup table in which a second resistance value R₁ corresponding to the current value, SOC value and temperature value of each region of the battery cell 200 is recorded. Accordingly, the controller 60 may determine the second resistance value of the target region by using the current value, SOC value, and temperature value of the target region, based on the second lookup table. In this case, the current value is a current value Iₙ at the current time point, the SOC value is a SOC value SOCₙ₋₁ determined at the previous time point, and the temperature value is also a temperature value Tₙ₋₁ determined at the previous time point.

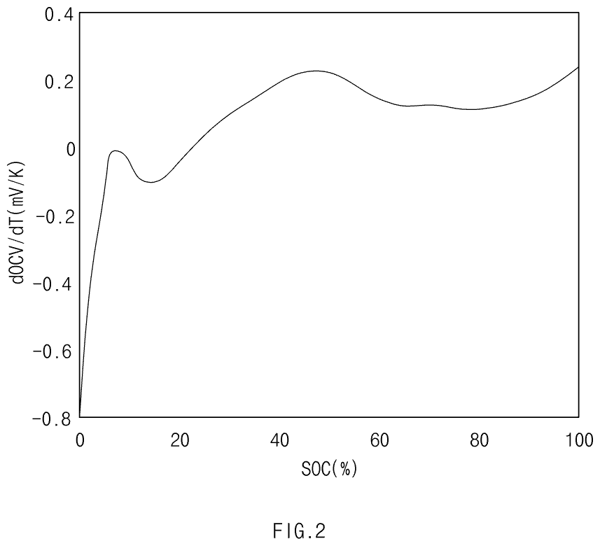

Meanwhile, the storage 10 may store a dOCV/dT map corresponding to each region of the battery cell 200. As an example, the dOCV/dT map is shown in FIG. 2.

FIG. 2 is a diagram illustrating an example of a dOCV/dT map stored in storage in an apparatus for diagnosing a state of a battery cell according to an embodiment of the present disclosure.

In FIG. 2, the horizontal axis represents SOC (%) for each region of the battery cell 200, and the vertical axis represents dOCV/dT (mv/K). Therefore, in the process of determining an amount of internal heat generation of a target region, the controller 60 may determine dOCV/dT by using the SOC of the target region.

In addition, the storage 10 may store a density p, a specific heat coefficient Cp, a heat conduction coefficient k, a volume V, a convection heat transfer coefficient h, a convection heat transfer surface area A, and the like of the battery cell 200 as fixed constant values.

The voltage sensor 20 may be provided on one side of the battery cell 200 to measure the total voltage of the battery cell 200.

The current sensor 30 may measure the total current of the battery cell 200.

The temperature sensor 40 may measure the outside temperature T_{Amb}.

The output device 50 may provide the temperature of each part of the battery cell 200 determined by the controller 60 to a user through voice or a screen. In addition, the output device 50 may provide state information of the battery cell 200 determined by the controller 60 to the user through voice or a screen.

The controller 60 may be electrically connected to each component and may perform overall control such that each component performs its function. The controller 60 may be implemented in the form of hardware or software, or may be implemented in a combination of hardware and software. Preferably, the controller 60 may be implemented as a microprocessor, but is not limited thereto.

Specifically, the controller 60 may divide the battery cell 200 into a plurality of regions, construct a Randle circuit for each region, determine a current value and a resistance value of each region based on the Randle circuit, determine the amount of internal heat generation of each region by using the current value and the resistance value, determine an amount of heat transfer and an amount of heat convection of each region based on an outside temperature value and a previous temperature value of each region, estimate a temperature of each region based on the amount of internal heat generation, the amount of heat transfer, and the amount of heat convection of each region, and diagnose the state of the battery cell by using the temperature of each region. In this case, the controller 60 may diagnose the state of the battery cell by using a temperature that is outside the normal range among the temperatures in each region.

For example, the controller 60 may determine that an abnormality occurs in the battery cell 200 when there is a temperature exceeding the upper limit reference value (e.g., 60° C.) among the temperatures in each region.

As another example, the controller 60 may determine that an abnormality occurs in the battery cell 200 when there is a temperature exceeding the lower limit reference value (e.g., −20° C.) among temperatures in each region.

As still another example, the controller 60 may set a first temperature section (e.g., 50° C. to 70° C.) with a risk level of ‘1’, a second temperature section (e.g., 70° C. to 80° C.) with a risk level of ‘2’, and a third temperature section (e.g., 80° C. to 90° C.) with a risk level of ‘3’. The controller 60 may classify the temperature for each region into each temperature section, and diagnose the state of the battery cell 200 based on the temperature section (e.g., the third temperature section) with the highest risk. In this case, when there is a temperature included in the third temperature section among the temperatures for each region, the controller 60 may diagnose the state of the battery cell 200 as a state in which thermal runaway may occur.

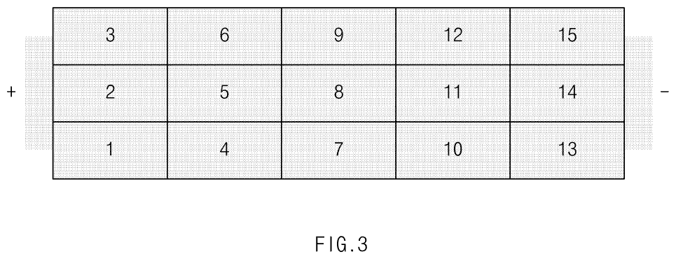

Hereinafter, the process of estimating the temperature of a target region by the controller 60 will be described with reference to FIGS. 3 to 6.

FIG. 3 is a diagram illustrating an example of a result of dividing a battery cell into a plurality of regions by the controller provided in an apparatus for diagnosing the state of a battery cell according to an embodiment of the present disclosure.

As shown in FIG. 3, the controller 60 may divide the battery cell 200 into 3×5 regions (region number 1 to region number 15). In this case, the controller 60 may determine the number of divided regions based on the temperature distribution according to the performance evaluation result of the battery cell 200 and the change pattern of the temperature distribution. In addition, in the case of a thermal management model for an indirect water-cooled battery pack, the controller 60 may determine the number of divided regions based on the shape of a coolant cooling channel. In addition, the controller 60 may determine the number of divided regions based on the contact structure between the cooling channel and the battery cell 200. In addition, the controller 60 may determine the number of divided regions by considering a calculated load.

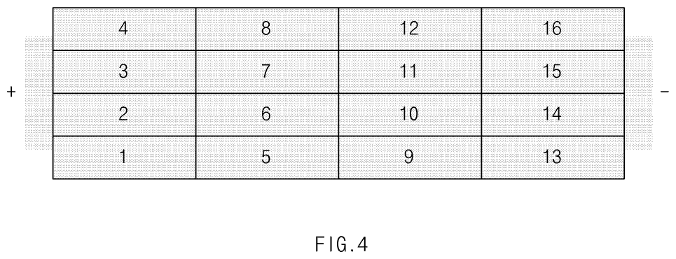

FIG. 4 is a diagram illustrating another example of a result of dividing a battery cell into a plurality of regions by the controller provided in an apparatus for diagnosing the state of a battery cell according to an embodiment of the present disclosure.

As shown in FIG. 4, the controller 60 may divide the battery cell 200 into 4×4 regions (region number 1 to region number 16). In this case, it is desirable that each region is divided equally, but the embodiment is not necessarily limited thereto.

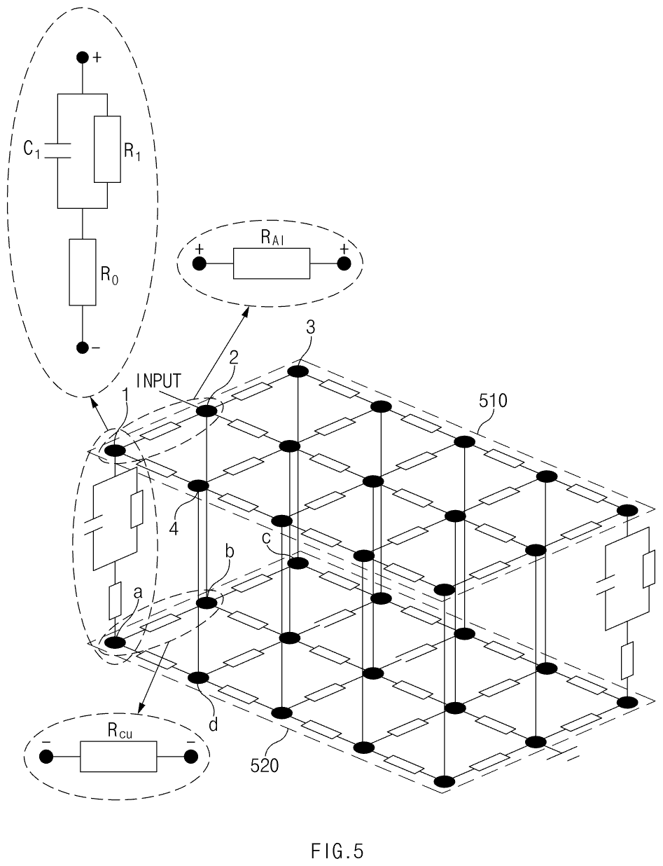

FIG. 5 is a diagram illustrating an example of a Randle circuit for each region of a battery cell generated by a controller provided in an apparatus for diagnosing the state of a battery cell according to an embodiment of the present disclosure.

In FIG. 5, reference numeral 510 is a portion corresponding to an aluminum current collector (i.e., a positive electrode current collector) of the battery cell 200, and a total of 15 points (or nodes) correspond to each region (a total of 15) of the battery cell 200 shown in FIG. 3. In this case, the location of point number 1 corresponds to the center on the aluminum current collector in region number 1 of the battery cell 200, the location of point number 2 corresponds to the center on the aluminum current collector in region number 2 of the battery cell 200, and the location of point number 3 corresponds to the center on the aluminum current collector in region number 3 of the battery cell 200.

In addition, reference numeral 520 is a portion corresponding to a copper current collector (i.e., a negative electrode current collector) of the battery cell 200, and a total of 15 points (or nodes) correspond to each region of the battery cell 200 shown in FIG. 3. In this case, the location of point number “a” corresponds to the center on the copper current collector in region number 1 of the battery cell 200, the location of point number “b” corresponds to the center on the copper current collector in region number 2 of the battery cell 200, and the location of point number “c” corresponds to the center on the copper current collector in region number 3 of the battery cell 200.

In addition, each point in region 510 and each point in region 520 are matched one-to-one with each other, and a Randle circuit is located between the matched points. For reference, in FIG. 5, considering drawing complexity, only the Randle circuit corresponding to region number 1 of the battery cell 200 and the Randle circuit corresponding to region number 15 of the battery cell 200 are shown, and the rest are expressed as straight lines. In this case, the Randle circuit may include one capacitor C₁ and two resistors R₀ and R₁. In addition, when the coordinates of point number 1 are (x, y), the coordinates of point number 2 are (x, y+1), and the coordinates of point number 4 are (x+1, y). In addition, when the coordinates of point number “a” are (x, y), the coordinates of point number “b” are (x, y+1), and the coordinates of point number “d” are (x+1, y).

In addition, a resistance value R_{Al} connecting each point included in region 510 and a resistance value R_{Cu} connecting each point included in region 520 may be fixed values, and may be stored in the storage 10.

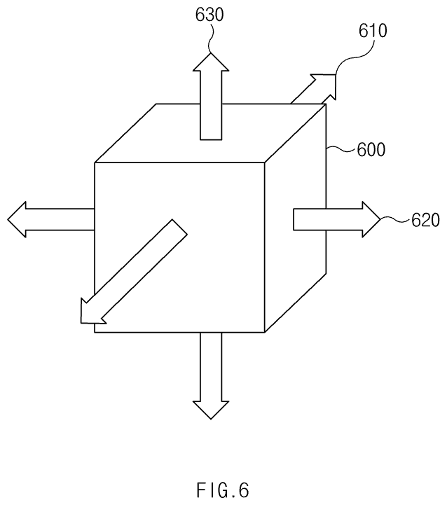

FIG. 6 is a diagram illustrating examples of heat conduction and heat convection in a target region of a battery cell generated by a controller provided in an apparatus for diagnosing a state of a battery cell according to an embodiment of the present disclosure.

In FIG. 6, reference numeral 600 represents the three-dimensional structure of a target region among a plurality of regions of the battery cell 200, reference numeral 610 represents heat conduction in the y-axis direction, reference numeral 620 represents heat conduction in the x-axis direction, and reference numeral 630 represents heat convection to the outside of the battery cell 200.

For example, when a 3D target region is region number 1, heat conduction to region number 4 (i.e., heat conduction in the x-axis direction) and heat conduction to region number 2 (i.e., heat conduction in the y-axis direction), and thermal convection may occur.

As another example, when the 3D target region is region number 2, heat conduction to region number 5 (i.e., heat conduction in the x-axis direction), heat conduction to region number 1 and region number 3 (i.e., heat conduction in the y-axis direction), and thermal convection may occur.

As still another example, when the 3D target region is region number 5, heat conduction to region number 2 and region number 8 (i.e., heat conduction in the x-axis direction), heat conduction to region number 4 and region number 6 (i.e., heat conduction in the y-axis direction), and thermal convection may occur.

Meanwhile, the controller 60 may determine a current value and a resistance value of each region based on the Randle circuit, determine the amount of internal heat generation of each region by using the current value and the resistance value, determine an amount of heat transfer and an amount of heat convection of each region based on an outside temperature value and a previous temperature value of each region, and estimate a temperature of each region based on the amount of internal heat generation, the amount of heat transfer, and the amount of heat convection of each region. For example, the controller 60 may estimate the temperature Ty for each region of the battery cell 200 based on following Equation 1.

$$ρ {C}_{p} \frac{\partial {T}_{n}}{\partial t} = {k}_{x} \frac{{\partial }^{2} {T}_{n - 1}}{\partial {x}^{2}} + {k}_{y} \frac{{\partial }^{2} {T}_{n - 1}}{\partial {y}^{2}} + {\dot{q}}_{a} - \frac{{\dot{Q}}_{diss}}{V} \qquad [ Equation 1 ]$$

Where p represents the density of the battery cell 200, Cp represents a specific heat coefficient, kₓ represents a heat conduction coefficient in the x-axis direction, k_{y} represents a heat conduction coefficient in the y-axis direction, “V” represents the volume of the battery cell 200, Tₙ₋₁ represents the temperature of the target region at a previous time, and \dot{q}ₐ represents the amount of internal heat generation in region “a” (e.g., 1 to 15). Additionally, the first term on the right side represents the amount of heat transfer in the x-axis direction, the second term represents the amount of heat transfer in the y-axis direction, the third term represents the amount of internal heat generation in the target region, and the fourth term represents the amount of heat convection in the target region. In this case, \dot{Q}_{diss} may be expressed as following Equation 2.

$${\dot{Q}}_{diss} = hA ( {T}_{n - 1} - {T}_{Amb} ) \qquad [ Equation 2 ]$$

Where ‘h’ represents a convective heat transfer coefficient, ‘A’ represents a convective heat transfer surface area, Tₙ₋₁ represents a temperature of a target region at a previous time point, and T_{Amb} represents an outside temperature.

The controller 60 may obtain the convection heat transfer coefficient “h” and the convection heat transfer surface area “A” stored in the storage 10, the temperature Tₙ₋₁ of the target region determined at the previous time point, and the outside temperature T_{Amb} through the temperature sensor 40, so that it is possible to determine \dot{Q}_{diss}.

In addition, the amount of internal heat generation \dot{q}ₐ of the target region may be expressed as following Equation 3.

$${\dot{q}}_{a} = \frac{{\dot{Q}}_{a}}{V} \qquad [ Equation 3 ]$$

Where ‘V’ represents the volume of the battery cell 200, and \dot{Q}ₐ may be expressed as following Equation 4.

$${\dot{Q}}_{a} = {I}^{2} ( {R}_{0} + {R}_{1} ) + I \times {T}_{n - 1} \frac{dOCV}{dT} + {I}^{2} ( {R}_{cc , pos} + {R}_{cc , neg} ) \qquad [ Equation 4 ]$$

Where ‘I’ is the current value of the target region, R₀ and R₁ are the resistance values of the target region, Tₙ₋₁ is the temperature value of the target region at the previous time point, R_{cc,pos} is the average value of the x-axis direction resistance value R_{Al,x} and the y-axis direction resistance value R_{Al,y} on the aluminum electrode plate (i.e. a current collector), and R_{cc,neg} is the average value of the x-axis direction resistance value R_{Cu,x} and the y-axis direction resistance value R_{Cu,y} on the copper electrode plate.

The controller 60 may determine the current value “T” and the resistance values R₀ and R₁ of the target region by using the Randle circuit for each region of the battery cell 200, and determine the dOCV/dT value by using the dOCV/dT map as shown in FIG. 2. In addition, because the controller 60 knows the x-axis direction resistance value R_{Al,x} and the y-axis direction resistance value R_{Al,y} on the aluminum electrode plate in the target region, the controller 60 may determine the average value of the x-axis direction resistance value R_{Al,x} and the y-axis direction resistance value R_{Al,y} on the aluminum electrode plate. In addition, because the controller 60 knows the x-axis direction resistance value R_{Cu,x} and the y-axis direction resistance value R_{Cu,y} on the copper electrode plate in the target region, the controller 60 may determine the average value of the x-axis direction resistance value Roux and the y-axis direction resistance value R_{Cu,y}.

Accordingly, the controller 60 may determine \dot{Q}ₐ and determine the amount of internal heat generation \dot{q}ₐ of the target region by dividing \dot{Q}ₐ by the volume “V” of the battery cell 200.

Ultimately, the controller 60 may estimate the temperature Tₙ of each region of the battery cell 200 based on Equation 1.

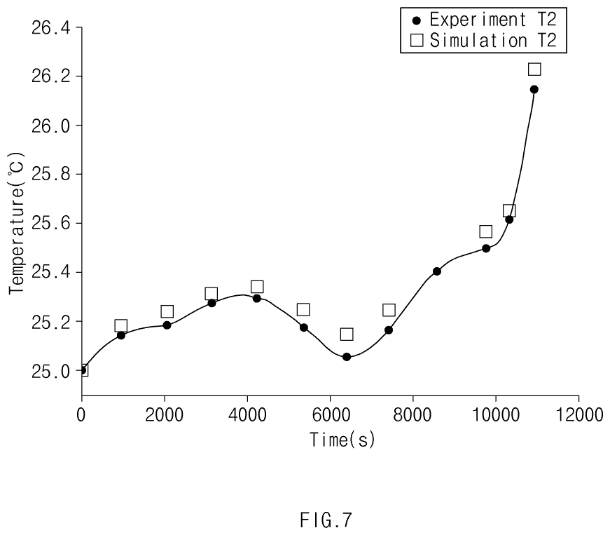

FIG. 7 is a diagram illustrating a first example of the temperature estimation performance of an apparatus for diagnosing a state of a battery cell according to an embodiment of the present disclosure, and illustrates the temperature T2 of region number 2 of the battery cell 200 determined by the controller 60.

In FIG. 7, the vertical axis represents temperature and the horizontal axis represents time. As may be understood through FIG. 7, it may be understood that the actual temperature value Experiment_T2 of region number 2 and the temperature value Simulation_T2 of region number 2 determined by the controller 60 are very similar.

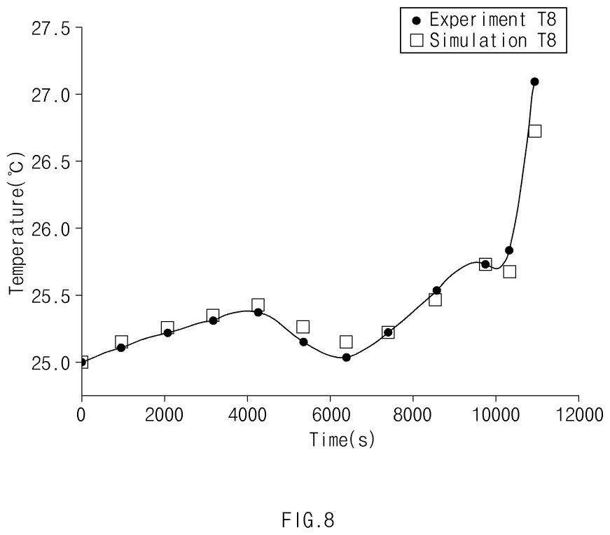

FIG. 8 is a diagram illustrating a second example of the temperature estimation performance of an apparatus for diagnosing a state of a battery cell according to an embodiment of the present disclosure, and illustrates the temperature T8 of region number 8 of the battery cell 200 determined by the controller 60.

In FIG. 8, the vertical axis represents temperature and the horizontal axis represents time. As may be understood through FIG. 8, it may be understood that the actual temperature value Experiment_T8 of region number 8 and the temperature value Simulation_T8 of region number 8 determined by the controller 60 are very similar.

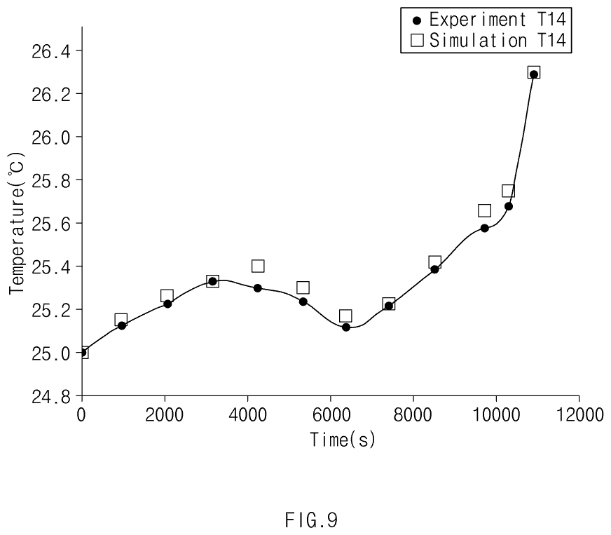

FIG. 9 is a diagram illustrating a third example of the temperature estimation performance of an apparatus for diagnosing a state of a battery cell according to an embodiment of the present disclosure, and illustrates the temperature of region number 14 of the battery cell 200 determined by the controller 60.

In FIG. 9, the vertical axis represents temperature and the horizontal axis represents time. As may be understood through FIG. 9, it may be understood that the actual temperature value Experiment_T14 of region number 8 and the temperature value Simulation_T14 of region number 14 determined by the controller 60 are very similar.

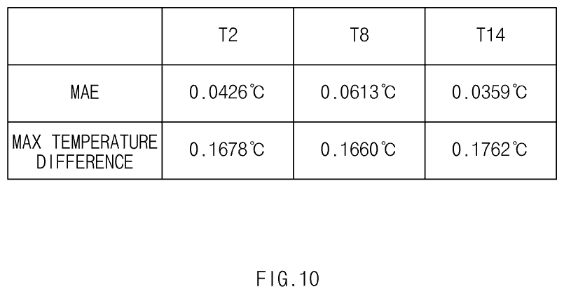

FIG. 10 is a diagram illustrating an example of a result of comparing the performances of an apparatus for diagnosing a state of a battery cell according to an embodiment of the present disclosure.

As shown in FIG. 10, the mean absolute error (MAE) of T2 is 0.0426° C., and the maximum temperature difference is 0.1678° C. The MAE of T8 is 0.0613° C., and the maximum temperature difference is 0.1660° C. The MAE of T14 is 0.0359° C., and the maximum temperature difference is 0.1762° C. Thus, it may be understood that the MAEs of all T2, T8 and T14 are very small, and the maximum temperature difference is also very small. In the end, it may be understood that the temperature estimation performance for each area of an apparatus for diagnosing a state of a battery cell according to an embodiment of the present disclosure is very excellent.

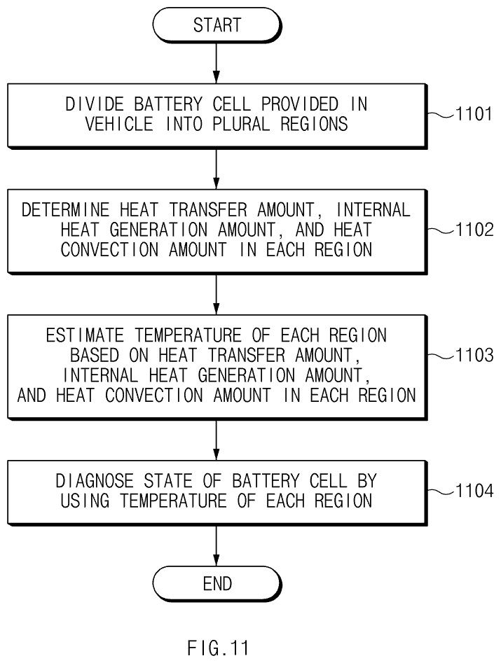

FIG. 11 is a flowchart illustrating a method of diagnosing a state of a battery cell according to an embodiment of the present disclosure.

First, in 1101, the controller 60 may divide the battery cell 200 into a plurality of regions.

Then, in 1102, the controller 60 may determine an amount of heat transfer, an amount of internal heat generation, and an amount of heat convection in each region.

Then, in 1103, the controller 60 may estimate a temperature of each region based on the amount of internal heat generation, the amount of heat transfer, and the amount of heat convection of each region.

Then, in 1104, the controller 60 may diagnose the state of the battery cell by using the temperature of each region.

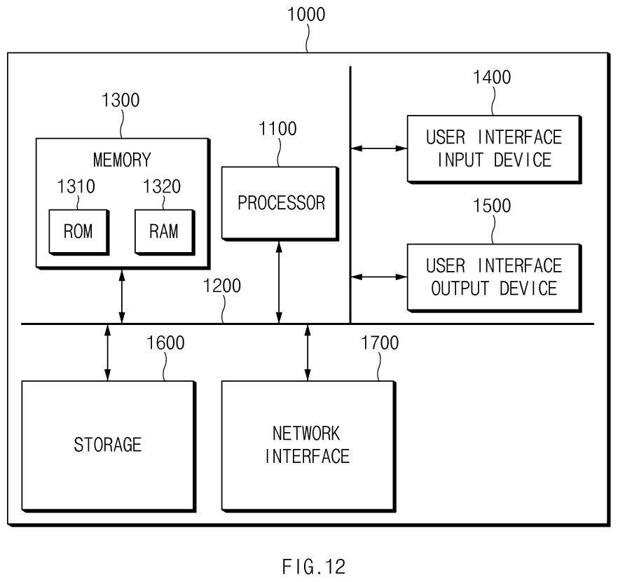

FIG. 12 is a block diagram illustrating a computing system for executing a method of diagnosing a state of a battery cell according to each embodiment of the present disclosure.

Referring to FIG. 12, as described above, the method of diagnosing a state of a battery cell according to an embodiment of the present disclosure may be implemented through a computing system 1000. The computing system 1000 may include at least one processor 1100, a memory 1300, a user interface input device 1400, a user interface output device 1500, storage 1600, and a network interface 1700 which are connected through a system bus 1200.

The processor 1100 may be a central processing unit (CPU) or a semiconductor device that processes instructions stored in the memory 1300 and/or the storage 1600. The memory 1300 and the storage 1600 may include various volatile or nonvolatile storage media. For example, the memory 1300 may include a read only memory (ROM) 1310 and a random access memory (RAM) 1320.

Accordingly, the processes of the method or algorithm described in relation to the embodiments of the present disclosure may be implemented directly by hardware executed by the processor 1100, a software module, or a combination thereof. The software module may reside in a storage medium (that is, the memory 1300 and/or the storage 1600), such as a RAM, a flash memory, a ROM, an EPROM, an EEPROM, a register, a hard disk, a detachable disk, or a CD-ROM. The exemplary storage medium is coupled to the processor 1100, and the processor 1100 may read information from the storage medium and may write information in the storage medium. In another method, the storage medium may be integrated with the processor 1100. The processor 1100 and the storage medium may reside in an application specific integrated circuit (ASIC). The ASIC may reside in a user terminal. In another method, the processor and the storage medium may reside in the user terminal as an individual component.

According to the embodiments, it is possible to diagnose the state of the battery cell with high accuracy by dividing the battery cell into a plurality of regions, constructing a Randle circuit for each region, determining a current value and a resistance value of each region based on the Randle circuit, determining the amount of internal heat generation of each region based on the current value and the resistance value, determining an amount of heat transfer and an amount of heat convection of each region based on an outside temperature value and a previous temperature value of each region, and estimating a temperature of each region based on the amount of internal heat generation, the amount of heat transfer, and the amount of heat convection of each region.

The above description is a simple exemplification of the technical spirit of the present disclosure, and the present disclosure may be variously corrected and modified by those skilled in the art to which the present disclosure pertains without departing from the essential features of the present disclosure. Therefore, the disclosed embodiments of the present disclosure do not limit the technical spirit of the present disclosure but are illustrative, and the scope of the technical spirit of the present disclosure is not limited by the embodiments of the present disclosure. The scope of the present disclosure should be construed by the claims, and it will be understood that all the technical spirits within the equivalent range fall within the scope of the present disclosure.

What is claimed is:

1. An apparatus for diagnosing a state of a battery cell, the apparatus comprising:
the battery cell provided in a vehicle; and
a controller configured to
divide the battery cell into a plurality of regions,
determine an amount of heat transfer, an amount of internal heat generation, and an amount of heat convection in each region,
estimate a temperature of each region based on the amount of internal heat generation, the amount of heat transfer, and the amount of heat convection of each region, and
diagnose the state of the battery cell by using the temperature of each region.

2. The apparatus of claim 1, wherein the controller is configured to diagnose the state of the battery cell by using a temperature outside a normal range among temperatures of the plurality of regions.

3. The apparatus of claim 1, wherein the controller is configured to classify the temperature of each region into a plurality of temperature sections and diagnose the state of the battery cell based on the temperature section with a highest risk among the plurality of temperature sections.

4. The apparatus of claim 1, wherein the controller is configured to construct a Randle circuit for each region, determine a current value and a resistance value of the Randle circuit, and determine the amount of internal heat generation of each region based on the current value and resistance value.

5. The apparatus of claim 1, wherein the controller is configured to determine an amount of heat transfer in an x-axis direction and an amount of heat transfer in a y-axis direction for each region.

6. The apparatus of claim 5, wherein the controller is configured to determine the amount of heat transfer in the x-axis direction for each region by using a previous temperature value of each region and a heat conduction coefficient in the x-axis direction.

7. The apparatus of claim 5, wherein the controller is configured to determine the amount of heat transfer in the y-axis direction for each region by using a previous temperature value of each region and a heat conduction coefficient in the y-axis direction.

8. The apparatus of claim 1, further comprising a temperature sensor configured to measure an outside temperature value.

9. The apparatus of claim 8, wherein the controller is configured to determine the amount of heat convection in each region by using a convective heat transfer coefficient, a convective heat transfer surface area, a previous temperature value of each region, the outside temperature value, and a volume of the battery cell.

10. The apparatus of claim 1, wherein the controller is configured to divide the battery cell into 3×5 regions or 4×4 regions.

11. A method of diagnosing a state of a battery cell, the method comprising:
dividing, by a controller, the battery cell provided in a vehicle into a plurality of regions;
determining, by the controller, an amount of heat transfer, an amount of internal heat generation, and an amount of heat convection in each region;
estimating, by the controller, a temperature of each region based on the amount of internal heat generation, the amount of heat transfer, and the amount of heat convection of each region; and
diagnosing, by the controller, the state of the battery cell by using the temperature of each region.

12. The method of claim 11, wherein the diagnosing of the state of the battery cell includes diagnosing the state of the battery cell by using a temperature outside a normal range among temperatures of the plurality of regions.

13. The method of claim 11, wherein the diagnosing of the state of the battery cell includes
classifying the temperature of each region into a plurality of temperature sections, and
diagnosing the state of the battery cell based on the temperature section with a highest risk among the plurality of temperature sections.

14. The method of claim 11, wherein the determining of the amount of heat transfer, the amount of internal heat generation, and the amount of heat convection in each region includes
constructing a Randle circuit for each region,
determining a current value and a resistance value of the Randle circuit, and
determining the amount of internal heat generation of each region based on the current value and resistance value.

15. The method of claim 11, wherein the determining of the amount of heat transfer, the amount of internal heat generation, and the amount of heat convection in each region includes
determining an amount of heat transfer in an x-axis direction for each region, and
determining an amount of heat transfer in a y-axis direction for each region.

16. The method of claim 15, wherein the determining of the amount of heat transfer in the x-axis direction for each region includes determining the amount of heat transfer in the x-axis direction for each region by using a previous temperature value of each region and a heat conduction coefficient in the x-axis direction.

17. The method of claim 15, wherein the determining of the amount of heat transfer in the y-axis direction for each region includes determining the amount of heat transfer in the y-axis direction for each region by using a previous temperature value of each region and a heat conduction coefficient in the y-axis direction.

18. The method of claim 11, further comprising measuring, by a temperature sensor, an outside temperature value.

19. The method of claim 18, wherein the determining of the amount of heat transfer, the amount of internal heat generation, and the amount of heat convection in each region includes determining the amount of heat convection in each region by using a convective heat transfer coefficient, a convective heat transfer surface area, a previous temperature value of each region, the outside temperature value, and a volume of the battery cell.

20. The method of claim 11, wherein the dividing of the battery cell into the plurality of regions includes dividing the battery cell into 3×5 regions or 4×4 regions.
